(19) United States
(12) Patent Application Publication
(10) Pub. No.: US 2010/0320552 A1
(43) Pub. Date: Dec. 23, 2010

(54) CMOS Image Sensor

(75) Inventors: Chien-Hsien Tseng, Hsin-Chu (TW); Chin-Poh Pang, Hsin-Chu (TW)

Correspondence Address: TUNG & ASSOCIATES / RANDY W. TUNG, ESQ., 838 W. LONG LAKE RD., SUITE 120, BLOOMFIELD HILLS, MI, 48302, US

(73) Assignee: Pixart Imaging Inc.

(21) Appl. No.: 12/487,776

(22) Filed: Jun. 19, 2009

(51) Int. Cl. H01L 31/00

(52) U.S. Cl. 257/432; 257/E31.001

(57) ABSTRACT

The present invention discloses a CMOS image sensor comprising: a substrate; a photo diode formed in the substrate; an interconnection formed on the substrate, wherein the portions of the interconnection are insulated from one another by a dielectric material; a light passage penetrating through at least part of the dielectric material; a micro lens above the light passage; and a color filter above the micro lens.

### FIELD OF INVENTION

The present invention relates to a CMOS image sensor.

### DESCRIPTION OF RELATED ART

FIG. 1 shows the cross section of one pixel in a CMOS image sensor, in which a PN junction forming a photo diode 12 is provided in a substrate 11. Several layers of interconnection 14 are formed above the photo diode 12, including a contact plug 14a, metal lines 14b, a via plug 14c, etc., wherein these portions of the interconnection are insulated from one another by a dielectric material 13. The topmost metal layer 14b is covered by a passivation layer 15 thereupon; a color filter 17 is provided above the passivation layer 15, and a micro lens 18 is provided above the color filter 17.

In addition to the abovementioned structure, it is preferable to provide a light passage 20 in the dielectric material 13 such that more light reaches the photo diode 12 through the dielectric material 13. With regard to the light passage and the CMOS image sensor, the following prior art references disclose relevant details: U.S. Pat. Nos. 6,861,686, 7,205,623, 7,400,003, 7,462,507, 7,193,289 and 7,342,268, and U.S. Publication No. 2007/0262366.

In the foregoing prior art references, the micro lens 18 is located above the color filter 17, far from the photo diode 12. It is disadvantageous because the focus effect is weaker.

### SUMMARY OF THE INVENTION

An objective of the present invention is to provide a CMOS image sensor having a micro lens 18 and a color filter 17 which are arranged in a way different from the prior art so as to increase the focus effect.

In order to achieve the foregoing objective, in one perspective of the present invention, it provides a CMOS image sensor comprising: a substrate; a photo diode formed in the substrate; an interconnection formed on the substrate, wherein the portions of the interconnection are insulated from one another by a dielectric material; a micro lens above the dielectric material; and a color filter above the micro lens.

The CMOS image sensor preferably further includes a light passage penetrating through at least part of the dielectric material.

The CMOS image sensor preferably further includes a passivation layer provided between the dielectric material and the micro lens, wherein the light passage either penetrates through the passivation layer or not.

The CMOS image sensor preferably further includes a planarization layer provided between the micro lens and the color filter, wherein the planarization layer can be made of a spin-on material such as a photoresist-like material or a spin-on glass.

The objectives, technical details, features, and effects of the present invention will be better understood with regard to the detailed description of the embodiments below, with reference to the drawings.

### BRIEF DESCRIPTION OF THE DRAWINGS

FIG. 1 is a cross-sectional view shows a prior art structure.

FIGS. 2-5 show four embodiments of the present invention, respectively.

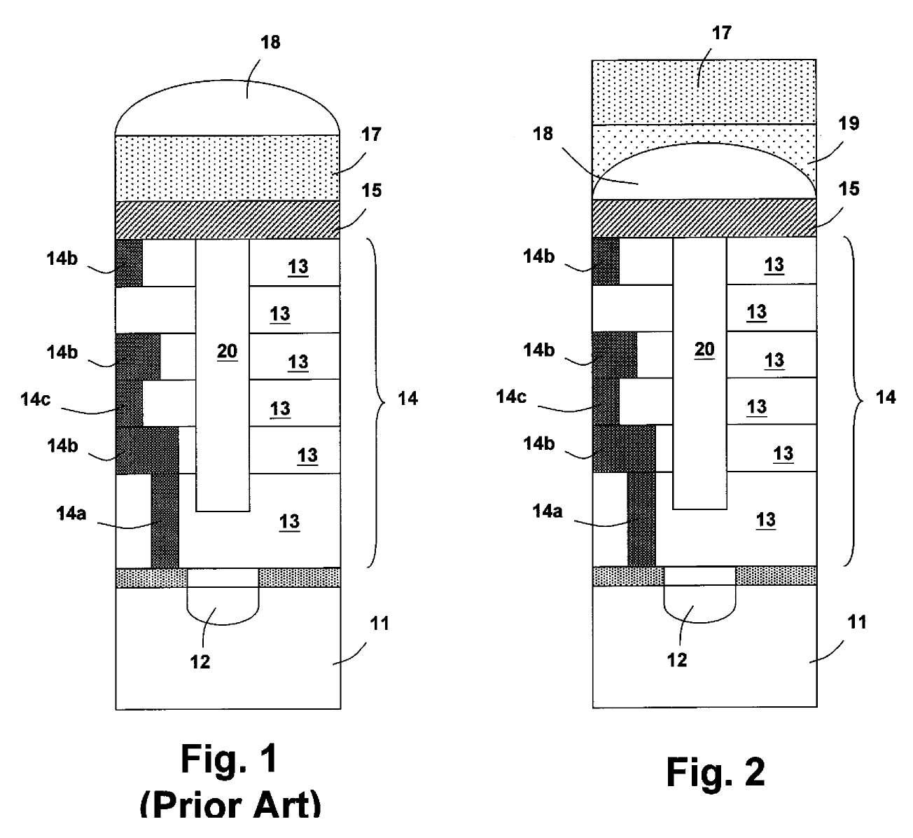

### DESCRIPTION OF THE PREFERRED EMBODIMENTS

The drawings as referred to throughout the description of the present invention are for illustration only, to show the interrelationships between the process steps and between the layers, but not drawn according to actual scale.

FIG. 2 illustrates the first embodiment of the present invention. According to this embodiment, first, a substrate 11 is provided, which for example can be a silicon substrate. A PN junction is made in the substrate 11 by ion-implantation to form a photo diode 12. Next, several layers of interconnection 14 are formed above the photo diode 12, including a contact plug 14a, metal lines 14b, a via plug 14c, etc., wherein these portions of the interconnection are insulated from one another by a dielectric material 13. After completion of the interconnection 14, preferably, a light passage 20 is formed by etching. A transparent material with higher light transmittance can be filled in the light passage 20, which may be an organic material, photo resist, spin-on glass, etc. The topmost metal layer 14b is covered by a passivation layer 15. In the abovementioned structure, the contact plug 14a, metal lines 14b and via plug 14c can be made of a material including tungsten, aluminum, copper, tungsten alloy, aluminum alloy, and copper alloy. The dielectric material 13 for example can be an oxide including silicon dioxide, fluorine doped silicon dioxide, or other materials with low dielectric constant. The passivation layer 15 for example includes a composite layer of a lower oxide layer and an upper nitride layer.

One difference between the present invention and the prior art is that the micro lens 18 is formed above the passivation layer 15 first. The micro lens 18 can be made of a material such as resin. In this embodiment, a planarization layer 19 can be further formed above the micro lens 18. This planarization layer 19 can be made of any transparent materials, which is preferably a spin-on material including a photoresist-like material or a spin-on glass. A color filter 17 is further formed above the planarization layer 19, which can be made of a conventional photosensitive color material commonly used to form the color filter.

Compared with the prior art, such arrangement is advantageous in that the micro lens 18 is located much closer to the photo diode 12. As a result, the micro lens 18 has a wider chief ray angle, and the photo diode 12 has a better light collection efficiency.

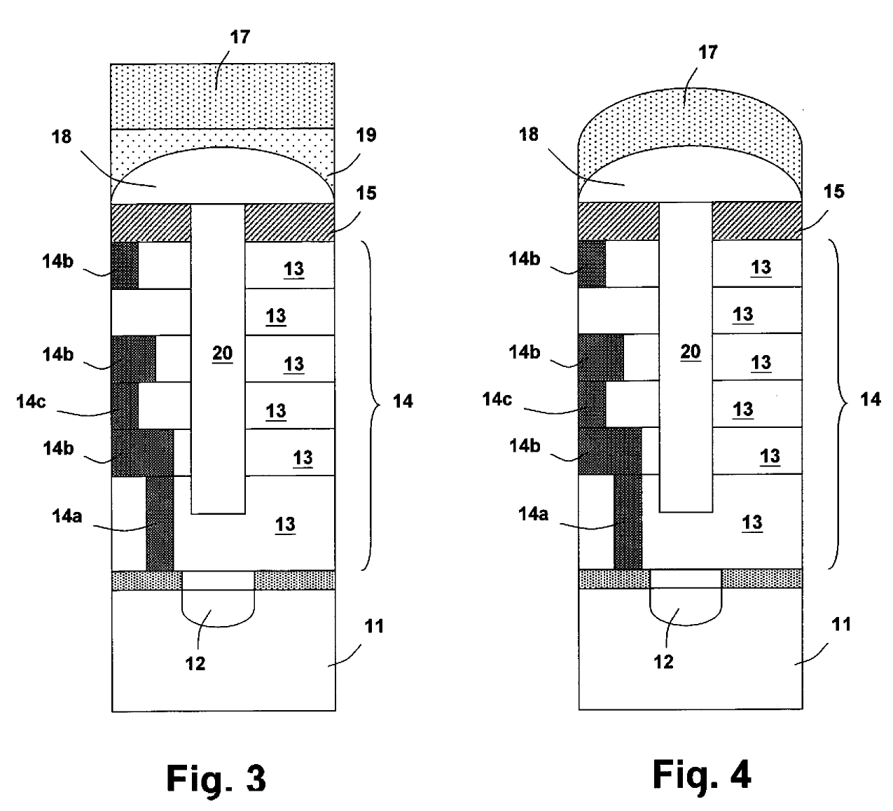

FIG. 3 illustrates the second embodiment of the present invention. In this embodiment, after the completion of an interconnection 14, a passivation layer 15 is formed first, and then a light passage 20 is formed by etching and a transparent material with higher light transmittance is filled therein. Thus, the light passage 20 penetrates through the passivation layer 15 so that the light collection efficiency of the light passage 20 increases (so does the light collection efficiency of the photo diode 12). Other parts of the CMOS image sensor are the same as the previous embodiment.

FIG. 4 illustrates the third embodiment of the present embodiment. In this embodiment, after the completion of an interconnection 14, a passivation layer 15 is formed first, and then a light passage 20 is formed by etching and a transparent material with higher light transmittance is filled therein. In addition, no planarization layer 19 is formed after a micro lens 18 is formed above the passivation layer 15. Instead, a color filter 17 is formed upon a micro lens 18 directly. Compared with the second embodiment, this embodiment saves the material and the step for forming the planarization layer 19. Other parts of the CMOS image sensor are the same as the second embodiment.

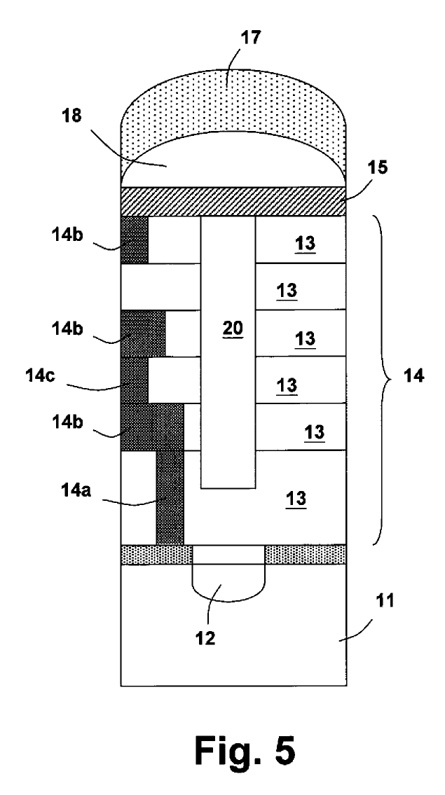

FIG. 5 illustrates the fourth embodiment of the present invention. In this embodiment, after the completion of an interconnection 14, first a light passage 20 is formed by etching and a transparent material with higher light transmittance is filled in the light passage 20, and then a passivation layer 15 is formed. In addition, no planarization layer 19 is formed after a micro lens 18 is formed above the passivation layer 15. Instead, a color filer 17 is formed directly upon the micro lens 18 directly. This embodiment is similar to the first embodiment, but it saves the material and the step for forming the planarization layer 19. Other parts of the CMOS image sensor are the same as the first embodiment.

Throughout the second embodiment to the fourth embodiment, similarly to the first embodiment, the micro lens 18 is much closer to the photo diode 12 than the prior art. As a result, the micro lens 18 has a wider chief ray angel, and the photo diode 12 has a better light collection efficiency.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, the materials, the number of metal layers, etc. in the foregoing embodiments are for illustration only and may be changed in various ways. Additional materials can be added between two structural layers as shown without departing from the fundamental spirit of the present invention, such as but not limited to: adding a barrier layer made of silicon nitride or silicon carbide between the dielectric material 13 and the metal layer; adding a light passage fill between the passivation layer and the micro lens; and adding a material of metal silicide below the passage plug and the contact plug to reduce resistance. The light passage is not a necessary element of the present invention. In view of the foregoing, the spirit of the present invention should cover all such and other modifications and variations, which should be interpreted to fall within the scope of the following claims and their equivalents.

What is claimed is:

1. A CMOS image sensor comprising:
a substrate;
a photo diode formed in the substrate;
an interconnection formed on the substrate, wherein the portions of the interconnection are insulated from one another by a dielectric material;
a micro lens above the dielectric material; and
a color filter above the micro lens.

2. The CMOS image sensor of claim 1, further comprising a light passage penetrating through at least part of the dielectric material, wherein the micro lens is located above the light passage.

3. The CMOS image sensor of claim 1, wherein a passivation layer is provided between the dielectric material and the micro lens.

4. The CMOS image sensor of claim 3, further comprising a light passage penetrating through at least part of the dielectric material, wherein the light passage penetrates through the passivation layer.

5. The CMOS image sensor of claim 3, further comprising a light passage penetrating through at least part of the dielectric material, wherein the light passage does not penetrate through the passivation layer.

6. The CMOS image sensor of claim i, wherein a planarization layer is provided between the micro lens and the color filter.

7. The CMOS image sensor of claim 6, wherein the planarization layer is made of a spin-on material.

8. The CMOS image sensor of claim 7, wherein the spin-on material includes a photoresist-like material or a spin-on glass.
